(19) United States
(12) Patent Application Publication
(10) Pub. No.: US 2026/0236642 A1
(43) Pub. Date: Aug. 13, 2026

(54) PROCESS TARGET OPTIMIZATION PROCESSES

(71) Applicant: GlobalFoundries U.S. Inc., Malta, NY (US)

(72) Inventors: Paul Jungmann, Wilsdruff (DE); Jeffrey Bowman Johnson, North Hero, VT (US)

(21) Appl. No.: 19/049,270

(22) Filed: Feb. 10, 2025

(51) Int. Cl. G06F 30/27

(52) U.S. Cl. CPC G06F 30/27

(57) ABSTRACT

The present disclosure relates to target optimization processes and, more particularly, to an advanced process control method for process target optimization and methods of use. The method includes: updating, by the computing device, target metrology values in a metrology vector with measured metrology values; predicting, by the computing device, an effect on a set of final process targets using the updated metrology vector using a model based on simulation data; adjusting, by the computing device, one or more downstream metrology targets in the metrology vector to achieve the set of final process targets; and applying, by the computing device, process retargeting for the one or more downstream metrology targets.

### BACKGROUND

The present disclosure relates to target optimization processes and, more particularly, to an advanced process control method for process target optimization and methods of use.

Advanced Process Control (APC) hinges on seamlessly integrating feedback mechanisms, predictive analytics, and adaptive systems within manufacturing processes. This integration optimizes operations, delivering consistent quality and reducing variability. Current APC methods use physics simulations from Technology Computer-Aided Design (TCAD) simulations. The TCAD simulations therefore do not provide real-time capabilities.

### SUMMARY

In an aspect of the disclosure, a method comprises: updating, by the computing device, target metrology values in a metrology vector with measured metrology values; predicting, by the computing device, an effect on a set of final process targets using the updated metrology vector using a model based on simulation data; adjusting, by the computing device, one or more downstream metrology targets in the metrology vector to achieve the set of final process targets; and applying, by the computing device, process retargeting for the one or more downstream metrology targets.

In an aspect of the disclosure, a computer program product comprises one or more computer readable storage media having program instructions collectively stored on the one or more computer readable storage media. The program instructions executable to: predict a test result on a proposed set of parameters with existing, target parameters for subsequent process steps using a regression model; and change multiple downstream process targets based on the predicted test result using a global optimization module.

In an aspect of the disclosure, a system comprises: a processor, a computer readable memory, one or more computer readable storage media, and program instructions collectively stored on the one or more computer readable storage media. The program instructions is executable to: update target metrology values in a metrology vector with measured metrology values; predict an effect on a set of wafer electrical test (WET) targets using the updated metrology vector using a learning model simulation; adjust one or more downstream critical process step (CPS) metrology targets in the metrology vector to achieve the set of WET targets; and apply process retargeting for the one or more downstream CPS metrology targets.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 depicts a cloud computing node according to an embodiment of the present disclosure.

FIG. 2 shows a block diagram of an exemplary processing engine in accordance with aspects of the disclosure.

FIGS. 3A-3C show example processes in accordance with aspects of the disclosure.

FIG. 4 shows a flowchart of an exemplary method in accordance with aspects of the present disclosure.

### DETAILED DESCRIPTION

The present disclosure relates to target optimization processes and, more particularly, to an advanced process control method for process target optimization and methods of use. In more specific embodiments, the advanced process control (APC) integrates a TCAD-enabled Machine Learning (TCAD-eML) model with a global Front End of Line (FEOL) optimization process to consider multiple upstream and downstream performance-critical inline measurements and processes, in real-time, to optimize semiconductor fabrication processes, e.g., achieve desired final processes and, more preferably, electric characteristics including, for example, wafer electrical test (WET) targets.

In embodiments, the present disclosure may be used with other characteristics such as chemical, optical or other physical characteristics to optimize process targets in many different technologies. To this end, it should be understood by one of skill in the art that the present disclosure should not be limited to physical simulations such as TCAD simulations and that other simulations such as, for example, chemical, optical and/or other physical simulations can be used herein to optimize process targets in many different technologies. Hereinafter, though, the present disclosure focuses on TCAD simulations and related electrical characteristics (e.g., targets) with the understanding that other simulations and characteristics are contemplated herein for process target optimization.

Advantageously, the TCAD-eML model allows real-time process target optimization using a holistic approach that has sufficient accuracy without the need to run separate TCAD simulations for each change in critical process steps (CPS) and subsequent critical inline measurements (which are time consuming and process intensive). For example, in embodiments, the holistic approach adjusts multiple processes using multivariate inputs and outputs with a simulation model. The simulation model may be, for example, a physical, chemical, optical, etc. model. In one illustrative example, the simulation model may be TCAD-eML modeling and optimization processes to achieve desired final processes (e.g., electrical characteristics including WET targets). Moreover, the APC described herein is robust (dealing with differences efficiently) and scalable (e.g., provides massive parallelization) by using data analytics approaches to deal with multidimensionality and the large size of process space.

In embodiments, the systems and processes described herein provide a technical solution to a technical problem related to APC methods in a semiconductor fabrication facility (or other facilities which benefit from optimization processes). The current APC methods, for example, cannot provide a sufficient combination of device model accuracy and real-time capability. As an example, current methods utilize simulations performed in a TCAD in either a feed backward APC or a feed forward APC method. The TCAD simulation is very time consuming and not a practical application to optimize a process in real-time. In addition, the current methods of feed backward APC and feed forward APC do not take a holistic approach as both processes only consider a single performance-critical inline measurement and related CPS.

As should be understood by those of skill in the art, the feed backward control method uses a single CPS and subsequent performance-critical inline measurement (e.g., metrology) of the CPS to optimize the fabrication processes to achieve process targets such as electrical characteristic targets. That is, the feed backward control method only considers and adjusts a single CPS in order to change the corresponding process(es) (e.g., CPS) without consideration for any other process controls or critical dimensions. In this way, the feed backward control method is only considering the single CPS and corresponding performance-critical inline measurement to meet electrical characteristic targets. On the other hand, the feed forward control method adjusts a next CPS based on a performance-critical inline measurement of an immediately previous CPS in attempt to achieve the WET targets. This scenario also only takes into consideration a single CPS. In both scenarios, the APC methods will need to run a new TCAD simulation to determine whether the CPSs will achieve its desired electrical characteristic targets. The TCAD simulations are slow and cannot provide real-time processes. Accordingly, current APC systems do not do re-targeting, but just change tool setting to better reach the standard target. This is especially true for feed backward APC.

In comparison, the systems and processes of the present disclosure consider multiple upstream and multiple downstream performance-critical inline measurements (e.g., metrologies) and related process control steps (multiple CPS), in combination. For example, the systems and processes determine how all upstream CPS affect all downstream metrology targets, and how a downstream CPS should be changed to compensate for any upstream metrologies and their process outcomes to achieve a set of electrical characteristic targets and, more generally, final processes such as CPS. The CPS may be, for example, implant processes, patterning processes, deposition processes, rapid thermal anneal processes, etc. The metrologies (e.g., performance-critical inline measurements) can be, for example, gate length, gate width, gate thickness, gate location, implant dosage, deposition thickness, etc.

To achieve these objectives, the systems and processes of the present disclosure utilize a global optimization module and a TCAD-eML model. The TCAD-eML can use historical data to determine the downstream metrologies based on CPS and what adjustments can be made to downstream CPS taking into consideration each the upstream CPS and related metrologies, to achieve a target metrology that meets electrical characteristic targets. Accordingly, the systems and processes redefine the output targets (compared to tuning the CPS to reach a defined target) and place an optimization loop around a regression model (e.g., TCAD-eML) to achieve efficiencies in fabrication processes that were otherwise previously unavailable.

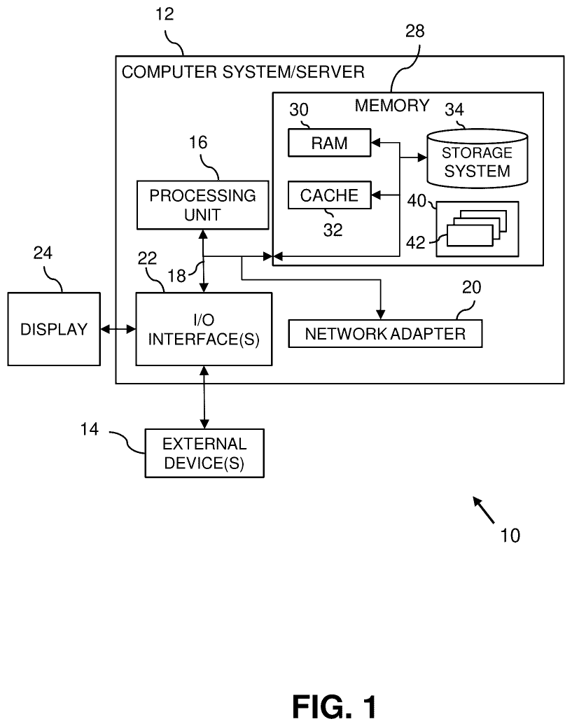

FIG. 1 depicts a cloud computing node according to an embodiment of the present disclosure. In this regard, the present disclosure may be representative of a system, a method, and/or a computer program product at any possible technical detail level of integration. The computer program product may include a computer readable storage medium (or media) having computer readable program instructions thereon for causing a processor to carry out aspects of the present disclosure. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination. A computer readable storage medium or media, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages. The computer readable program instructions may execute entirely on the user's computer, partly on the user's computer, as a stand-alone software package, partly on the user's computer and partly on a remote computer or entirely on the remote computer or server.

As described in more detail with respect to FIG. 1, these computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

Referring now to FIG. 1, a schematic of an example of a cloud computing node is shown. Cloud computing node 10 is only one example of a suitable cloud computing node and is not intended to suggest any limitation as to the scope of use or functionality of embodiments of the disclosure described herein. Regardless, cloud computing node 10 is capable of being implemented and/or performing any of the functionality set forth hereinabove. Also, it is to be understood that although this disclosure includes a detailed description on cloud computing, implementation of the teachings recited herein are not limited to a cloud computing environment. Rather, embodiments of the present disclosure are capable of being implemented in conjunction with any other type of computing environment now known or later developed.

In cloud computing node 10 there is a computer system/server 12, which is operational with numerous other general purpose or special purpose computing system environments or configurations. In embodiments, the computer system/server 12 (which may be internal or external to a processing tool) may perform the functions described herein, including, for example, (i) obtaining nozzle images from a camera, (ii) analyzing the nozzle images and identifying nozzle faults using imaging default detection, and (iii) interlocking the faults by, for example, notifications, tool inhibits, and/or lot holding processes.

In specific embodiments, the computer system/server 12 provides process target optimization based on a TCAD-eML model and a global optimization module, each of which can be implemented with the computer system/server 12. For example, the computer system/server 12 may establish a vector of metrology targets, one or more for each CPS chosen to achieve a set of electrical characteristic targets. After each CPS, the target metrology values in the metrology vector will be replaced with the actual measured metrology values (process outcome as noted in the TCAD). After each CPS, the TCAD-eML model will predict the effect on target processes with the updated metrology vector in real-time. The processes using the global optimization module will utilize the new metrologies and electrical data obtained from the TCAD-eML model to refine and adjust downstream CPSs and their metrology targets (e.g., provide a new set of device parameters) in the metrology vector to achieve the desired set of electrical characteristic targets. The processes will then proceed to the next, downstream, CPS where the TCAD-eML model will again predict the electrical characteristics (electrical data) based on the given set of metrology data in the metrology vector in real-time. Accordingly, the downstream CPS metrology targets are determined by a global optimization method based on the TCAD-eML model in a looped process.

Computer system/server 12 may be described in the general context of computer system executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, computer system/server 12 in cloud computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the disclosure.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the disclosure as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Also, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

As should be understood by those of skill in the art, a cloud computing environment includes one or more cloud computing nodes 10 with which local computing devices used by cloud consumers. Nodes 10 may communicate with one another. They may be grouped (not shown) physically or virtually, in one or more networks, such as Private, Community, Public, or Hybrid clouds as described hereinabove, or a combination thereof. This allows cloud computing environment to offer infrastructure, platforms and/or software as services for which a cloud consumer does not need to maintain resources on a local computing device. The model described herein may be scalable with the cloud computing environment.

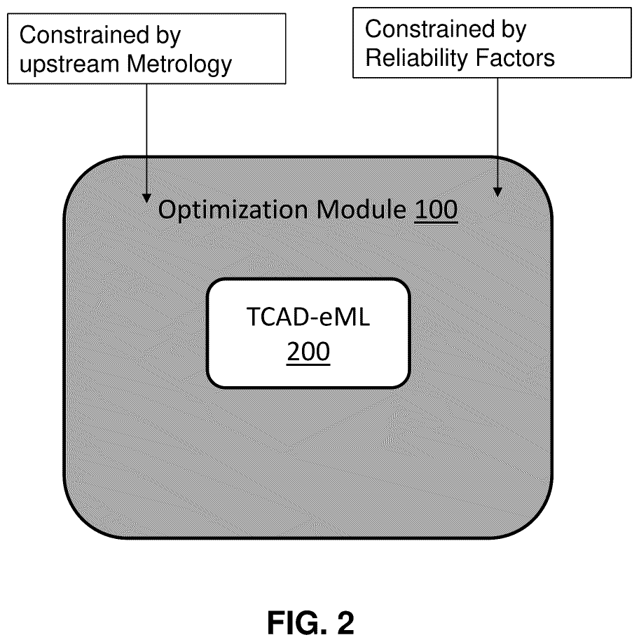

FIG. 2 shows a block diagram of an exemplary processing engine in accordance with aspects of the disclosure. In embodiments, the block diagram includes a global optimization module 100 with a TCAD-eML model 200. In embodiments, the global optimization module 100 is a framework that allows engineers to design and embed optimization-based control and monitoring modules on such autonomous highly dynamical systems. In the field of semiconductor fabrication, the global optimization module 100 leverages advanced data analytics, machine learning, and artificial intelligence (AI), that analyzes vast amounts of real-time process data from a fab to identify critical parameters and automatically adjust them to maximize yield, minimize defects, and optimize overall production efficiency across various stages of semiconductor manufacturing, e.g., wafer cleaning, photolithography, etching, annealing and deposition processes, etc. As should be understood by those of skill in the art, the global optimization module 100 provides may benefits including, e.g., improved yield by identifying and mitigating process variations, reduced manufacturing costs by optimizing process parameters, faster time to market by enabling rapid process adjustments to meet changing product requirements, and enhanced quality control by proactively identifying and mitigating potential defects.

In further embodiments, the global optimization module 100 provides the following functionalities, amongst others:
1. Continuously gathers data from sensors and equipment across the fab to monitor key process variables like temperature, pressure, chemical concentrations, and device characteristics;
2. Utilizes statistical methods to identify process variations and potential issues before they impact yield;
3. Conducts controlled experiments to understand the impact of different process parameters on device performance and identify optimal settings;
4. Applies regression analysis, decision trees, or neural networks to identify complex relationships within the data and predict optimal process adjustments;
5. Simulates different scenarios and predict potential issues before they occur; and
6. Automatically adjusts process parameters based on real-time data analysis to maintain optimal conditions.

The global optimization module 100 may be constrained by upstream metrologies. That is, the metrology vector may be constrained by upstream metrology measurements, transistor reliability factors and ML model limitations. This includes, for example, constraints on inputs which should not be possible due to the constraints physically existing on a wafer. The global optimization module 100 may also be constrained by reliability factors, e.g., transistor reliability issues. Also, the global optimization module 100 may be constrained by limits of the TCAD-eML model 200, e.g., training data related constraints such as gate length and other parameters.

The TCAD-eML model 200 may be a machine learning regression model trained on a data set derived from TCAD processes and device simulation of the technology being manufactured. The regression model may be, for example, regression neural network models, higher order polynomial regression models, regression random forest models and/or extreme gradient boosting regression models. And, in embodiments, TCAD simulations are now used to build the TCAD-eML which can be used to accelerate transistor simulations in order to approximate the TCAD simulations during implementation of the processes described herein. Also, it should be recognized that the training data from the TCAD processes is influenced only by parameters that are set to vary and, hence, generate high quality data with minimal noise, compared to using actual fab data which may have inconsistent measurement locations, tool and material influences etc. It should be understood, though, that the TCAD-eML model may use fab data as it becomes more consistent with lower nose.

The TCAD-eML model 200 may be used to analyze and predict semiconductor device behavior by leveraging data generated from detailed physics-based simulations performed using known TCAD tools, utilizing the high-fidelity simulations to train machine learning models for faster and more efficient design optimization and analysis in the semiconductor industry. By running numerous TCAD simulations with varying parameters, e.g., critical dimensions, material properties and process related specifications, a large dataset of device electrical characteristics is generated, which serves as training data for machine learning models. These large datasets may be obtained from years of historical simulations. The trained machine learning model can thus be used to quickly predict device performance based on CPS parameters, without the need to run full TCAD simulations for every design iteration, significantly accelerating the design process.

The TCAD-eML provides many benefits including, amongst others:
1. Providing near-instantaneous predictions, allowing for rapid design exploration and optimization;
2. Capturing complex physical phenomena and providing more accurate predictions by utilizing detailed TCAD simulations for training data; and
3. Lowering computational costs associated with device design.

In implementation, the global optimization module 100 takes into consideration all of the CPSs, their related process targets and their actual outcomes to provide process optimization. At each step and with this information, the global optimization module 100 proposes a set of device parameters based on the process outcomes of the previous CPSs to adjust upcoming CPSs. For example, the global optimization module 100 establishes a vector of metrology targets, one or more for each CPS, chosen to achieve a set of electrical characteristic such as wafer electrical test (WET) targets. The TCAD-eML model 200 will utilize the proposed new set of device parameters in combination with the previous CPSs, their actual outcomes and the subsequent CPSs and their target outcomes to predict a set of eTest data (e.g., electrical characteristic targets). That is, after each CPS, the target metrology values in the metrology vector with the measured metrology values can be updated and the effect on the electrical characteristic of the updated metrology vector can be predicted by the TCAD-eML model 200. In this way, the TCAD-eML model 200 can predict the electrical characteristic targets based on a given, updated CPS and metrology vectors in real-time.

In embodiments, the global optimization module 100 compares the updated metrology vector (and related CPS) to a desired electrical characteristic target, e.g., WET characteristic or other characteristics including optical, chemical or other physical characteristics. If the desired electrical characteristic target has favorable electrical characteristics, e.g., meets a certain, predetermined threshold, the optimization engine 100 can optimize the CPSs to meet the desired electrical characteristic target. In other words, the optimization engine 100 can adjust downstream CPS to provide updated metrology targets in the metrology vector to achieve the set of electrical characteristic targets and, thereafter, the process can proceed to the next, downstream CPS. These processes are iterative (are provided in a loop) such that the next set of parameters (e.g., metrology for a retargeted CPS as determined by the optimization engine), will be considered and analyzed as described herein, taking into consider all previous processes and their process outcomes.

Accordingly, the global optimization module 100 integrates knowledge from physics simulations (TCAD simulations) into the APC methods with the help of physics-informed Machine Learning regression models (e.g., TCAD-eML). Also, instead of using individual CPS, all performance-defining FEOL processes are included in the analysis. In this way, a holistic approach which combines the influence from previous process outcomes with the adjustment of subsequent CPS to meet suggested outcome targets, in addition to considering all performance-dominant processes together to optimize the CPS and inline targets.

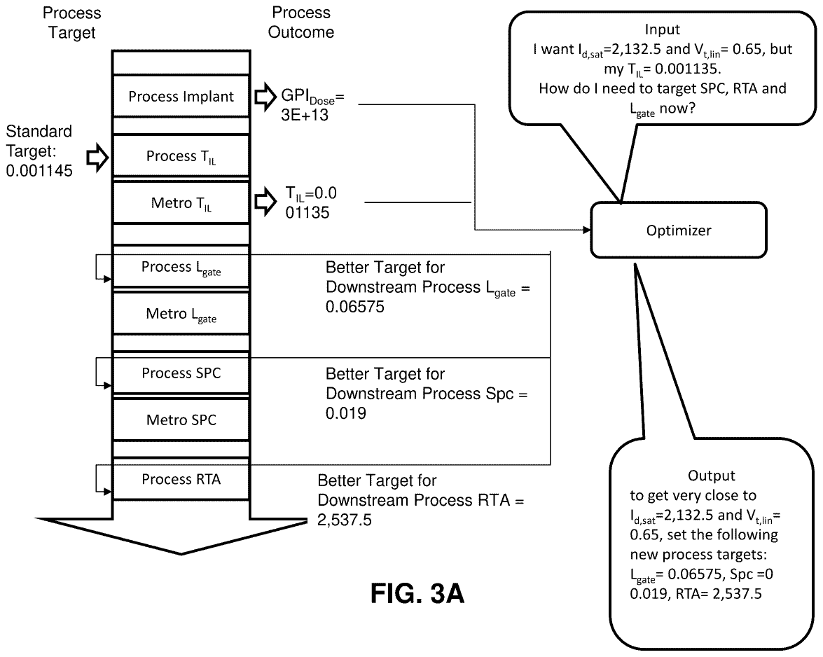

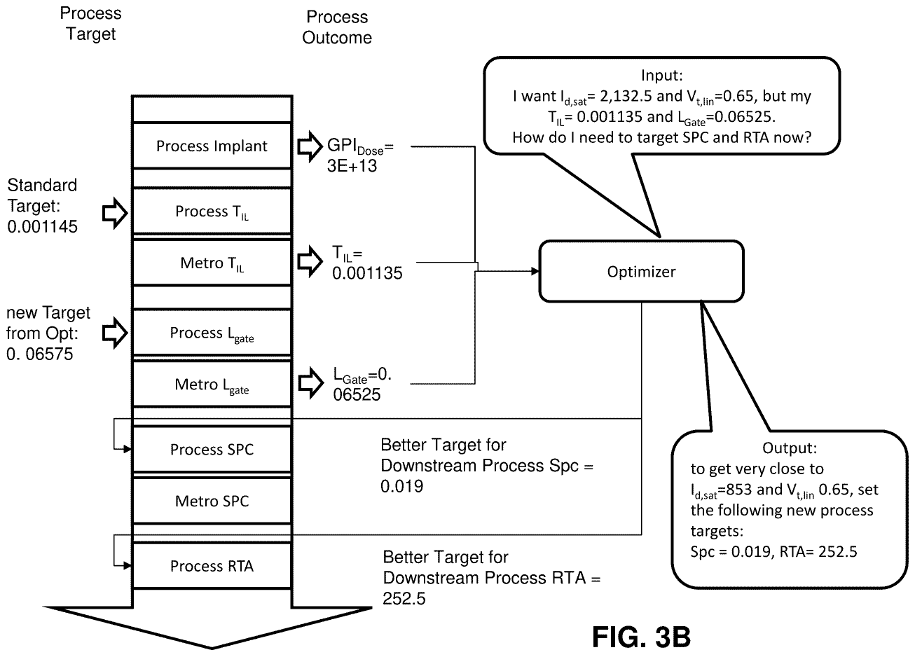

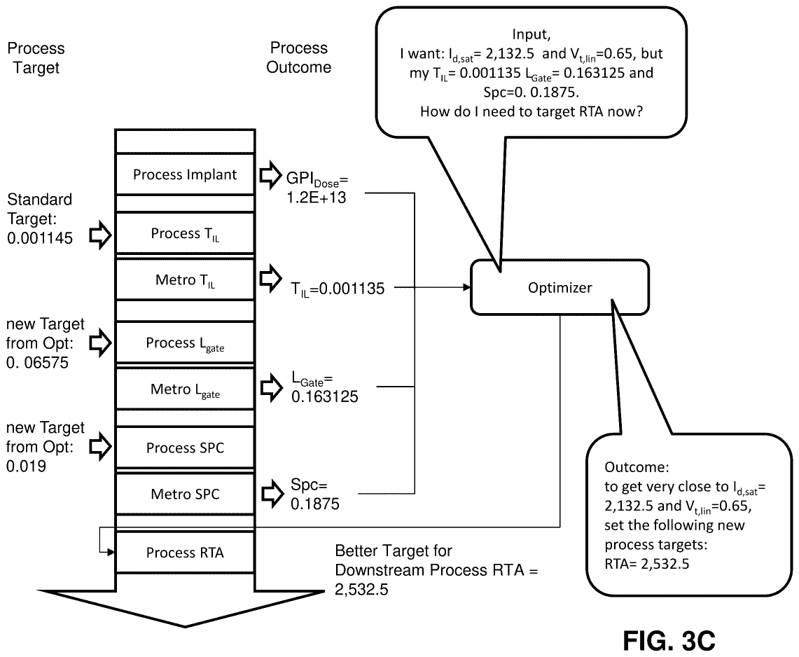

FIGS. 3A-3C show example processes in accordance with aspects of the disclosure. More specifically, FIGS. 3A-3C show multiple metrology readouts, with each readout being fed into the global optimization module, and the global optimization module changing multiple downstream (optimization) targets. As shown in each of FIGS. 3A-3C, each of the figures shows a process target and a process outcome for each different CPS, e.g., process implant, process T_{IL}, process L_{gate}, process SPC and process RTA, with their respective metrologies (e.g., metro T_{IL}, metro L_{gate}, metro SPC and metro RTA).

As depicted in FIG. 3A, the process implant and process T_{IL} have been run and their respective metrology outcomes have been determined. With the noted processes and respective metrology outcomes, the input to the global optimization module would be “I want I_{d,sat}=2,132.5 and V_{t,lin}=0.65, but my T_{IL}=0.001135. How do I need to target SPC, RTA and L_{gate} now?” Utilizing the processes described herein and taking into account the already performed processes and respective metrology outcomes, the global optimization module will determine future CPS to achieve the desirable outcomes as tested in the TCAD-eML, e.g., “to get very close to I_{d,sat}=2,132.5 and V_{t,lin}=0.65, set the following new process targets: L_{gate}=0. 06575, Spc=0.019, RTA=2,537.5”.

As shown in FIG. 3B, the next process is run, e.g., process L_{gate}, with the process outcome determined. In this example, the input to the global optimization module would be “I want I_{d,sat}=2,132.5 and V_{t,lin}=0.65, but my T_{IL}=0.001135and L_{Gate}=0.06525. How do I need to target SPC and RTA now?” Utilizing the processes described herein and taking into account the already performed processes and respective metrology outcomes, the global optimization module will determine future CPS to achieve the desirable outcomes as tested in the TCAD-eML, e.g., “to get very close to I_{d,sat}=2,132.5 and V_{t,lin}=0.65, set the following new process targets: Spc=0.019, RTA=2,535”.

Similarly, as shown in FIG. 3B, the next process is run, e.g., process SPC, with the process outcome determined. In this example, the input to the global optimization module would be “I want I_{d,sat}=2,132.5 and V_{t,lin}=0.65, but my T_{IL}=0.001135, L_{Gate}=0.06525 and Spc=0.01875. How do I need to target RTA now? ” Utilizing the processes described herein and taking into account the already performed processes and respective metrology outcomes, the global optimization module will determine future CPS to achieve the desirable outcomes as tested in the TCAD-eML, e.g., “to get very close to I_{d,sat}=2,132.5 and V_{t,lin}=0.65, set the following new process targets: RTA=2,532.5”. In this way, multiple upstream and downstream performance-critical inline measurements are taken into account when optimizing the fabrication processes, using TCAD eML models to run electrical tests to ensure that any change in a CPS and its accompanying outcome (taking into consideration subsequent processes and targets) will meet electrical characteristic targets.

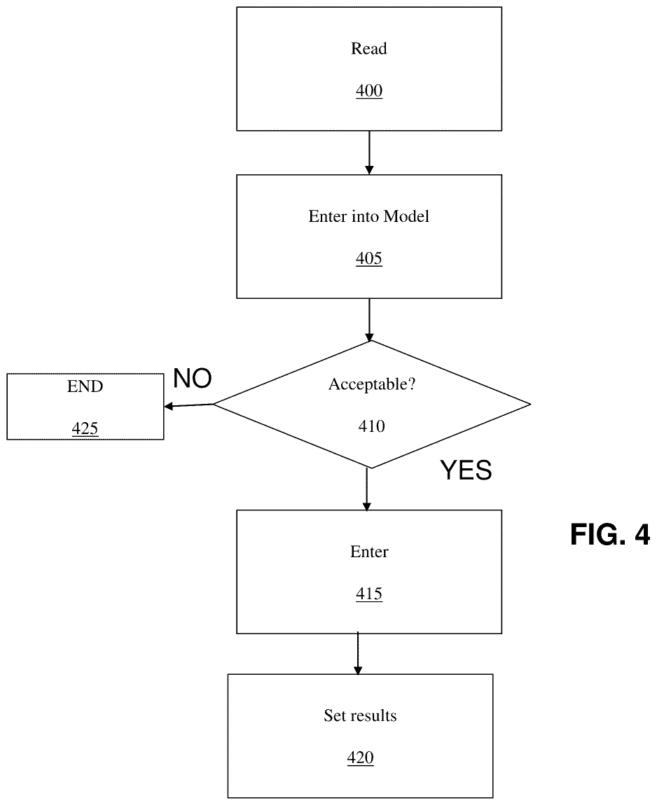

FIG. 4 shows a flowchart of an exemplary method in accordance with aspects of the present disclosure. Steps of the method may be carried out in the environment of FIGS. 1 and 2. The flowchart also illustrates the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Referring to FIG. 4, at step 400 the processes read physical measurement data (upstream process outcomes) from one or more sources. At step 405, the physical measurement data is entered into a TCAD-eML model to generate expected quality parameters (electrical device characteristics). At step 410, the processes determine whether the predicted quality parameters are acceptable. If the quality parameters are not acceptable, at step 415, the physical data is fed into an optimization module (based on a TCAD-eML model) that varies the not yet available physical measurements (downstream process outcomes/targets) with regard to the quality parameters (electrical device characteristics). At step 420, the processes, e.g., global optimization module, sets the optimization results taking into consideration constrained device parameters for optimal quality parameters as downstream process targets. If the predicted quality parameters are acceptable, the process ends at step 425.

The processes described herein can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A method comprising:
updating, by the computing device, target metrology values in a metrology vector with measured metrology values;
predicting, by the computing device, an effect on a set of final process targets using the updated metrology vector using a model based on simulation data;
adjusting, by the computing device, one or more downstream metrology targets in the metrology vector to achieve the set of final process targets; and
applying, by the computing device, process retargeting for the one or more downstream metrology targets.

2. The method of claim 1, wherein the establishing the vector of metrology targets is chosen to achieve the final process targets.

3. The method of claim 2, wherein the model based on simulation data comprises TCAD-simulation data.

4. The method of claim 3, wherein the TCAD-trained ML model comprises a regression model.

5. The method of claim 4, wherein the final process targets comprise wafer electric test result (WET) targets and the regression model predicts the WET targets based on a given metrology vector in real-time.

6. The method of claim wherein the simulation data comprises a TCAD-trained ML model trained on a data set derived from TCAD processes and device simulation of a technology being manufactured.

7. The method of claim 1, wherein the downstream metrology targets are critical process step (CPS) metrology targets which are determined by a global optimization method.

8. The method of claim 1, wherein the metrology vector is constraint by upstream metrology measurements, transistor reliability factors and model limitations.

9. The method of claim 1, wherein an outcome of the retargeted process is implemented as a parameter in a TCAD simulation.

10. A computer program product comprising one or more computer readable storage media having program instructions collectively stored on the one or more computer readable storage media, the program instructions executable to:
predict a test result on a proposed set of parameters with existing, target parameters for subsequent process steps using a regression model; and
change multiple downstream process targets based on the predicted test result using a global optimization module.

11. The computer program product of claim 10, wherein the regression model comprises physical simulations.

12. The computer program product of claim 11, wherein the physical simulations comprise a machine learning model based on TCAD data sets and the predicted test result comprises an electrical test.

13. The computer program product of claim 12, wherein the data sets comprise device parameters and process control steps from past simulations.

14. The computer program product of claim 10, further comprising comparing the predicted test result to a favorable test result and retargeting subsequent process steps when the predicted test result meets a predetermined threshold.

15. The computer program product of claim 10, wherein the predicting the test result comprises a wafer electrical test which considers all individual processes and related process outcomes of the individual processes.

16. The computer program product of claim 15, wherein all the previous individual processes and their respective process outcomes are combined together with subsequent processes and their respective process outcomes to predict the wafer electrical test.

17. The computer program product of claim 10, further comprising constraining a metrology vector when determining a change to process control steps.

18. The computer program product of claim 17, wherein the constraining includes considering upstream metrology measurements, transistor reliability factors and model limitations.

19. The computer program product of claim 10, wherein the regression model comprises a TCAD regression model and the changing of the multiple downstream process targets is performed by a global optimization module.

20. A system comprising:
a processor, a computer readable memory, one or more computer readable storage media, and program instructions collectively stored on the one or more computer readable storage media, the program instructions executable to:
update target metrology values in a metrology vector with measured metrology values;
predict an effect on a set of wafer electrical test (WET) targets using the updated metrology vector using a machine learning model simulation;
adjust one or more downstream critical process step (CPS) metrology targets in the metrology vector to achieve the set of WET targets; and
apply process retargeting for the one or more downstream CPS metrology targets.
